(19) United States
(12) Patent Application Publication
(10) Pub. No.: US 2015/0333621 A1
(43) Pub. Date: Nov. 19, 2015

(54) DETECTOR HAVING OFFSET CANCELLATION FUNCTION, AND POWER FACTOR CORRECTION APPARATUS AND POWER SUPPLYING APPARATUS HAVING THE SAME

(71) Applicant: SAMSUNG ELECTRO-MECHANICS CO., LTD., Suwon-Si (KR)

(72) Inventors: Jeong Mo YANG, Suwon-Si (KR); Man Dong Lee, Suwon-Si (KR); Yu Jin Jang, Suwon-Si (KR); Hwan Cho, Suwon-Si (KR)

(73) Assignee: SAMSUNG ELECTRO-MECHANICS CO., LTD., Suwon-si (KR)

(21) Appl. No.: 14/625,622

(22) Filed: Feb. 18, 2015

(30) Foreign Application Priority Data
May 14, 2014 (KR) 10-2014-0057689

(51) Int. Cl. H02M 1/42; H03K 5/003; H03F 3/45

(52) U.S. Cl. CPC H02M 1/4208; H03F 3/45076; H03K 5/003

(57) ABSTRACT

A detector having an offset cancellation function, and a power factor correction apparatus and a power supplying apparatus having the same are provided. The detector detecting a level of an input signal may include a level shifter shifting the level of the input signal, and a comparator amplifying a voltage difference between the level of the signal shifted by the level shifter and a ground, and providing a compensation current according to an offset generated at the time of amplifying a voltage to cancel the offset.

### CROSS-REFERENCE TO RELATED APPLICATION

This application claims the priority and benefit of Korean Patent Application No. 10-2014-0057689, filed on May 14, 2014, with the Korean Intellectual Property Office, the disclosure of which is incorporated in its entirety herein by reference.

### BACKGROUND

Some embodiments of the present disclosure may relate to a detector having an offset cancellation function canceling an offset of a detected voltage, and a power factor correction apparatus and a power supplying apparatus having the same.

In general, a high efficiency power supplying apparatus having a simple structure and a small size and stably supplying power may be needed in devices, such as computers, printers, copy machines, monitors, communications terminals, and the like.

The power supplying apparatus may impose limitations on harmonic content caused by an input terminal of an electronic device in order to reduce inefficient influence in an input power line and reduce interference in an external electronic device. A power factor correction apparatus, a power factor correction circuit, may be used to satisfy the limitations on the harmonic wave. The above-mentioned power factor correction apparatus uses a power factor correction mode, and may be classified as a passive mode power factor correction apparatus and an active mode power factor correction apparatus. Currently, active mode power factor correction apparatuses are more commonly used than passive mode power factor correction apparatuses.

The active mode power factor correction apparatus is classified as a continuous conduction mode (CCM) power factor correction apparatus, a critical conduction mode (CRM) power factor correction apparatus, and a discontinuous conduction mode (DCM) power factor correction apparatus, depending on a waveform of a current flowing in an inductor adopted for use therein.

Here, such a CRM power factor correction apparatus may detect the time when the current flowing in the inductor has a level of zero, in order to turn on a switch after a predetermined delay time. The inductor current may be sensed by a sensing resistor between a ground and an output in which alternating current (AC) power is rectified. Therefore, a voltage detecting circuit, for detecting a voltage having a level lower than 0V, may need to sense the current.

### RELATED ART DOCUMENT

U.S. Patent Application Publication No. 2003/0095421

### SUMMARY

Some embodiments of the present disclosure may provide a detector having an offset cancellation function, and a power factor correction apparatus and a power supplying apparatus having the same.

According to an aspect of the present disclosure, a detector, detecting a level of an input signal, may include: a level shifter shifting the level of the input signal; and a comparator amplifying a voltage difference between the level of the signal shifted by the level shifter and a ground, and providing a compensation current according to an offset generated at the time of amplifying a voltage to cancel the offset.

According to another aspect of the present disclosure, a power factor correction apparatus may include: a power factor correcting unit correcting a power factor of input power; a controlling unit controlling an operation of the power factor correcting unit according to an output signal of the power factor correcting unit and a detection signal obtained by detecting a level of the input power; and a detector detecting a current level of the input power to provide the detected current level to the controlling unit, amplifying the detected current level at the time of detecting the current level, and providing a compensation current according to an offset generated at the time of amplifying a voltage to cancel the offset.

According to another aspect of the present disclosure, a power supplying apparatus may include: a power factor correcting unit correcting a power factor of input power; a power converting unit converting the power of which the power factor has been corrected by the power factor correcting unit into driving power and outputting the driving power; a controlling unit controlling an operation of the power factor correcting unit according to an output signal of the power factor correcting unit and a detection signal obtained by detecting a level of the input power; and a detector detecting a current level of the input power to provide the detected current level to the controlling unit, amplifying the detected current level at the time of detecting the current level, and providing a compensation current according to an offset generated at the time of amplifying a voltage to cancel the offset.

The comparator may have an offset canceling period and a signal detecting period after the offset canceling period, and the offset canceling period and the signal detecting period may be repeated.

The comparator may include a first transconductance amplifier amplifying the voltage difference between the level of the signal shifted by the level shifter and the ground; and a second transconductance amplifier providing a compensation current according to an offset generated by an amplification operation of the first transconductance amplifier. The first transconductance amplifier may have an output signal which is input to the second transconductance amplifier, and the output signal of the first transconductance amplifier and an output signal of the second transconductance amplifier may be combined and output.

The comparator may further include: a first switch connected between an output terminal of the level shifter and an input terminal of the first transconductance amplifier; a second switch connected between a terminal of the first switch and the ground; a third switch connected between an output terminal of the first transconductance amplifier and an input terminal of the second transconductance amplifier; and a capacitor connected between the input terminal of the second transconductance amplifier and the ground. The comparator may further include an inverting amplifier invert-amplifying an output signal generated by using or combining the output signal of the first transconductance amplifier and the output signal of the second transconductance amplifier.

The first and second switch may be turned-on and the third switch may be turned-off during the offset canceling period, and the first and second switches may be turned-off and the third switch may be turned-on during the signal detecting period.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic circuit diagram of a power supplying apparatus according to an exemplary embodiment of the present disclosure;

FIG. 2 is a schematic circuit diagram of a detector adopted in the power supplying apparatus illustrated in FIG. 1;

FIG. 3 is a schematic circuit diagram of a comparator illustrated in FIG. 2; and

FIGS. 4A, 4B, and 4C are graphs illustrating main signal waveforms in a case in which an offset does not occur, a case in which a negative (−) offset occurs, and a case in which a positive (+) offset occurs, respectively.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

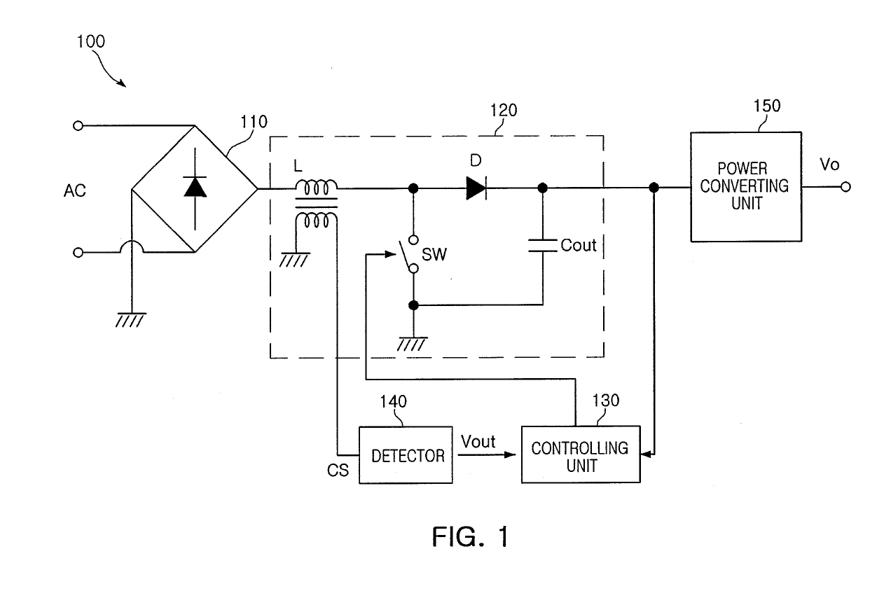

FIG. 1 is a schematic circuit diagram of a power supplying apparatus according to an exemplary embodiment of the present disclosure.

Referring to FIG. 1, a power supplying apparatus 100 according to an exemplary embodiment of the present disclosure may include a power factor correcting unit 120, a controlling unit 130, a detector 140, and a power converting unit 150.

The power factor correcting unit 120 may correct a power factor by switching input power. In the case in which alternating current (AC) power is input to the power supplying apparatus 100, power rectified by a rectifying unit 110 may be input to the power factor correcting unit 120.

The power factor correcting unit 120 may include an inductor L, a power switch SW, a diode D, and a capacitor Cout.

The inductor L may charge/discharge and output power having a level of power rectified according to the switching operation of the power switch SW. Thus, for example, a voltage level may be increased and a phase difference between a voltage and a current may be corrected, thereby correcting a power factor.

The diode D may provide a power transfer path. The capacitor Cout may stabilize the output power and transfer the stabilized power to the power converting unit 150.

The power converting unit 150 may convert the power having the power factor, corrected in the power factor correcting unit 120, into driving power Vo, and output the converted driving power Vo.

The controlling unit 130 may control the switching operation of the power switch SW depending on, for instance, but not limited to, a level of the power having the corrected power factor and/or a level of the rectified power.

For example, the level of the rectified power may be a level of a current flowing in the inductor L, but not limited thereto.

The detector 140 may detect the level of current flowing in the inductor L, and may also detect a zero current.

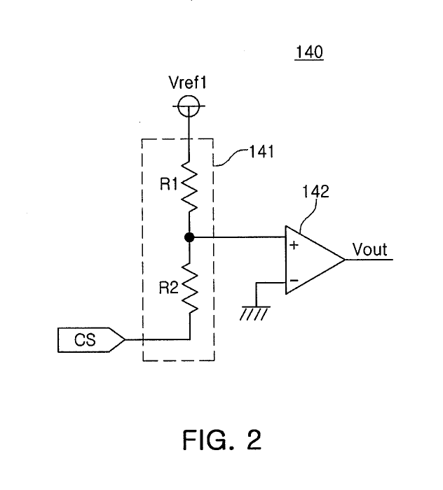

FIG. 2 is a schematic circuit diagram of a detector adopted in the power supplying apparatus illustrated in FIG. 1.

Referring to FIG. 2, the detector 140 may include a level shifter 141 and a comparator 142.

The level shifter 141 may be configured to include first and second resistors R1 and R2. The first resistor R1 may be connected to an input terminal to which a reference voltage Vref1 is input, and the second resistor R2 may be connected to a detecting terminal detecting the current flowing in the inductor L. A threshold voltage for the detection of the current by the detector 140 may be represented by Vcszcd and may be expressed by the following Equation 1.

Vcszcd=−Vref1*(R2/R1) (Equation 1)

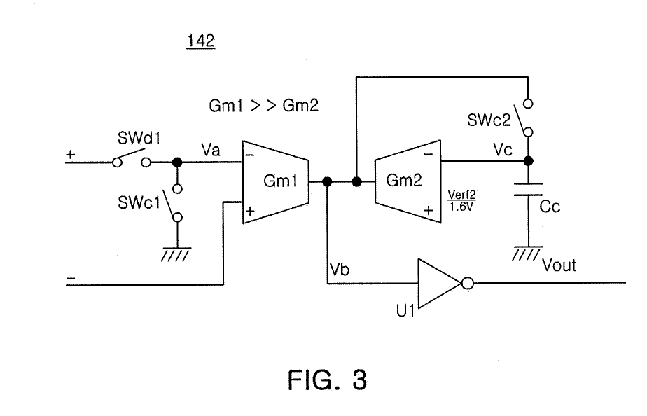

FIG. 3 is a schematic circuit diagram of the comparator illustrated in FIG. 2.

Referring to FIG. 3, the comparator 142 may include first and second amplifiers Gm1 and Gm2. The first and second amplifiers Gm1 and Gm2 may be, for example, but not limited to, transconductance amplifiers. In addition, the comparator 142 may include an inverting amplifier U1.

The first amplifier Gm1 may amplify a voltage difference between positive (+) and negative (−) input terminals of the comparator 142. The second amplifier Gm2 may perform an offset cancellation function. The inverting amplifier U1 may amplify an output from the first amplifier Gm1 so that a voltage output Vout by the comparator 142 may have relatively smooth waveform.

In the case in which a voltage gain obtained by the first amplifier Gm1 is sufficiently high, an input offset voltage of the comparator 142 may mainly occur from an input offset voltage of the first amplifier Gm1 (therefore, only cancellation of the input offset voltage of the first amplifier Gm1 will be considered).

The comparator 142 may have an offset canceling period, and a signal detecting period after terminating the offset canceling period in an operating interval. The offset canceling period and the signal detecting period may be repeated.

During a process in which the offset cancellation is performed, first and second switches SWc1 and SWc2 may be turned-on and a third switch SWd1 may be turned-off. Thus, both input terminals of the first amplifier Gm1 may be connected to a ground. In a case in which the input of the first amplifier Gm1 does not have an offset voltage, a current output by the first amplifier Gm1 may be ‘0’. Here, in order to adjust a balance in the comparator 142, a level of a current output by the second amplifier Gm2 may be 0.

For a simple description, for example, if the second amplifier Gm2 does not have an input offset voltage, a level of a voltage Vc stored in an offset cancellation capacitor Cc may be equal to that of a reference voltage Vref2 of the second amplifier Gm2.

On the other hand, for example, if the first amplifier Gm1 has any offset voltage Voff1, the second amplifier Gm2 may need to supply any current to compensate for the current output by the first amplifier Gm1 by the offset voltage. Thus, the voltage Vc stored in the offset cancellation capacitor Cc may be expressed by the following Equation 2.

Vc−Vref2=Voff1*(GM1/GM2) (Equation 2)

where GM1 and GM2 refer to transconductance of the first and second amplifiers Gm1 and Gm2, respectively. Here, it can be indicated that when GM1 is designed to be greater than GM2 in the above-mentioned Equation 2, a small amount of the input offset voltage of the comparator 142 may be adjusted together with adjusting a relatively significant amount of voltage stored in the offset cancellation capacitor Cc.

Here, an effect by an abnormal charge injected into the offset cancellation capacitor Cc from the second switch SWc2 may be reduced. In addition, a level of a Gm1 common mode voltage in a cancellation circuit may be 0, and this voltage may be the same common mode voltage for sensing.

Meanwhile, during signal detection, the third switch SWd1 may be turned-on and the first and second switches SWc1 and SWc2 may be turned-off. In order to perform the signal detection, the first amplifier Gm1 may be operated together with the inverting amplifier U1. In this case, the second amplifier Gm2 may continuously supply a current for compensation together with the supply of the voltage stored in the offset cancellation capacitor Cc.

The first and second amplifiers Gm1 and Gm2 may be configured by, for example, but not limited to, a P channel MOSFET composed of a differential pair, and the currents supplied by the first and second amplifiers Gm1 and Gm2 may be added to each other, transferred to a current mirror (not illustrated), copied, and converted to be finally connected to an final output. As illustrated in FIG. 3, the first and second amplifiers Gm1 and Gm2 may share an output terminal. The inverting amplifier U1 may be configured to include, for instance, but not limited to, a CMOS inverter and a common source amplifier configured of a P-channel MOSFET. The first to third switches SWc1, SWc2, and SWd1 are configured to include, for example, but not limited to, an N-channel MOSFET, and the offset cancellation capacitor Cc may form a Cc value by capacitance of a gate terminal of the N-channel MOSFET of the third switch SWd1.

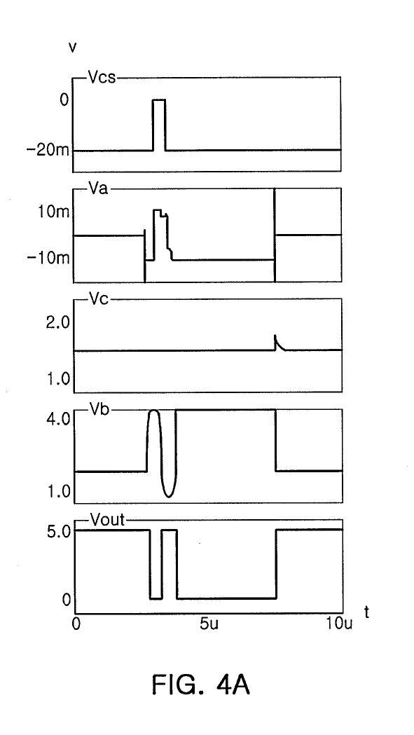

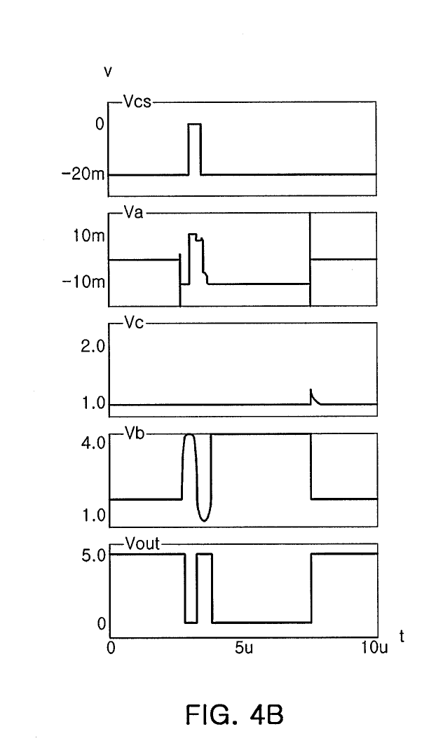

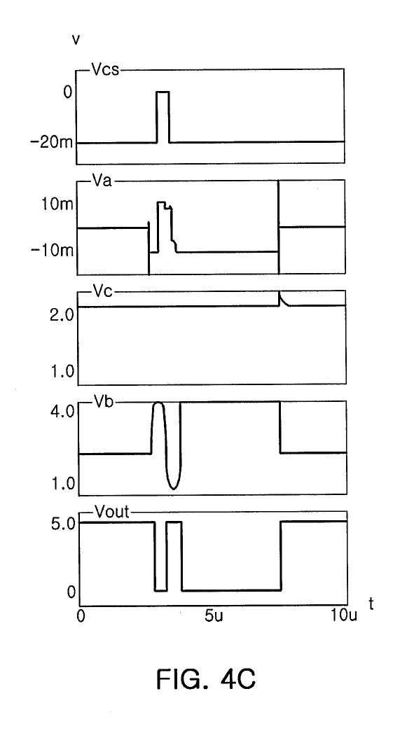

FIGS. 4A, 4B, and 4C are graphs illustrating main signal waveforms in a case in which an offset does not occur, a case in which a negative (−) offset occurs, and a case in which a positive (+) offset occurs, respectively.

Referring to FIGS. 3, 4A, 4B, and 4C, waveforms when the offset voltage is 0V (FIG. 4A), −25 mV (FIG. 4B), and 25 mV (FIG. 4C) in the case in which the zero current is in a range of time of 2.5 μs to 7.5 μs are illustrated. The offset canceling operation may be performed after 7.5 μs.

An input voltage Va of the first amplifier Gm1 during the offset canceling period may be 0V, and an input voltage Vc of the second amplifier Gm2 may have the same high level as those of an output voltage Vb and the output voltage Vout of the inverting amplifier U1.

In a zero current detecting period, the input voltage Vc of the second amplifier Gm2 may have the same voltage level as that in the offset canceling period, and the input voltage Va of the first amplifier Gm1 may not be 0V, but may have a voltage level higher than a voltage level Vcs of a detection signal by 10 mV. The output voltage Vb and the output voltage Vout from the inverting amplifier U1 may be changed to a level matched to that of the input voltage Va of the first amplifier Gm1.

In detail, it may be appreciated that the input voltage Vc of the second amplifier Gm2 may be set to a predetermined level matched to that of the offset voltage Voff, but the offset voltage Voff may not influence the output voltage Vout. Here, the cancellation of the offset voltage Voff may be verified.

As set forth above, according to some exemplary embodiments of the present disclosure, the zero current detecting operation may be accurate, whereby malfunctioning of the circuit or a distribution problem in detecting IC characteristics may be solved.

While exemplary embodiments have been shown and described above, it will be apparent to those skilled in the art that modifications and variations could be made without departing from the scope of the present invention as defined by the appended claims.

What is claimed is:

1. A detector detecting a level of an input signal, the detector comprising:
a level shifter shifting the level of the input signal; and
a comparator amplifying a voltage difference between the level of the signal shifted by the level shifter and a ground, and providing a compensation current according to an offset generated by amplification of a voltage.

2. The detector of claim 1, wherein the comparator has an offset canceling period and a signal detecting period.

3. The detector of claim 2, wherein the offset canceling period and the signal detecting period are repeated.

4. The detector of claim 1, wherein the comparator comprises:
a first transconductance amplifier amplifying the voltage difference between the level of the signal shifted by the level shifter and the ground; and
a second transconductance amplifier providing the compensation current according to the offset generated by the amplification of the first transconductance amplifier.

5. The detector of claim 4, wherein the first transconductance amplifier outputs an output signal to the second transconductance amplifier, and
the output signal of the first transconductance amplifier and an output signal of the second transconductance amplifier are combined.

6. The detector of claim 4, wherein the comparator further comprises:
a first switch connected between an output terminal of the level shifter and an input terminal of the first transconductance amplifier;
a second switch connected between a terminal of the first switch and the ground;
a third switch connected between an output terminal of the first transconductance amplifier and an input terminal of the second transconductance amplifier; and
a capacitor connected between the input terminal of the second transconductance amplifier and the ground.

7. The detector of claim 4, wherein the comparator further comprises an inverting amplifier inverting-amplifying an output signal generated by using the output signal of the first transconductance amplifier and the output signal of the second transconductance amplifier.

8. The detector of claim 6, wherein the first and second switches are turned-on and the third switch is turned-off during an offset canceling period, and
the first and second switches are turned-off and the third switch is turned-on during a signal detecting period.

9. A power factor correction apparatus, comprising:
a power factor correcting unit correcting a power factor of input power;
a controlling unit controlling the power factor correcting unit according to the corrected power factor of the input power and a detection signal obtained by detecting a current level of the input power; and
a detector detecting the current level of the input power, amplifying the detected current level, and providing a compensation current according to an offset generated by amplification of a voltage.

10. The power factor correction apparatus of claim 9, wherein the detector comprises:
a level shifter shifting the current level of the input power; and
a comparator amplifying a voltage difference between the current level of the power shifted by the level shifter and a ground, and providing the compensation current according to the offset generated at a time of amplifying the voltage to cancel the offset.

11. The power factor correction apparatus of claim 10, wherein the comparator has an offset canceling period and a signal detecting period.

12. The power factor correction apparatus of claim 11, wherein the offset canceling period and the signal detecting period are repeated.

13. The power factor correction apparatus of claim 10, wherein the comparator comprises:
a first transconductance amplifier amplifying the voltage difference between the shifted current level of the power and the ground; and
a second transconductance amplifier providing the compensation current according to the offset generated by amplification of the first transconductance amplifier.

14. The power factor correction apparatus of claim 13, wherein the first transconductance amplifier outputs an output signal to the second transconductance amplifier, and
the output signal of the first transconductance amplifier and an output signal of the second transconductance amplifier are combined.

15. The power factor correction apparatus of claim 13, wherein the comparator further comprises:
a first switch connected between an output terminal of the level shifter and an input terminal of the first transconductance amplifier;
a second switch connected between a terminal of the first switch and the ground;
a third switch connected between an output terminal of the first transconductance amplifier and an input terminal of the second transconductance amplifier; and
a capacitor connected between the input terminal of the second transconductance amplifier and the ground.

16. The power factor correction apparatus of claim 14, wherein the comparator further comprises an inverting amplifier inverting-amplifying an output signal generated by using the output signal of the first transconductance amplifier and the output signal of the second transconductance amplifier.

17. The power factor correction apparatus of claim 15, wherein the first and second switches are turned-on and the third switch is turned-off during an offset canceling period, and
the first and second switches are turned-off and the third switch is turned-on during a signal detecting period.

18. A power supplying apparatus, comprising:
a power factor correcting unit correcting a power factor of input power;
a power converting unit converting the power corrected by the power factor correcting unit into driving power and outputting the driving power;
a controlling unit controlling the power factor correcting unit according to the corrected power factor of the input power and a detection signal obtained by detecting a current level of the input power; and
a detector detecting the current level of the input power, amplifying the detected current level, and providing a compensation current according to an offset generated by amplification of a voltage.

19. The power supplying apparatus of claim 18, wherein the detector comprises:
a level shifter shifting the current level of the input power; and
a comparator amplifying a voltage difference between the current level of the input power shifted by the level shifter and a ground, and providing a compensation current according to the offset generated at a time of amplifying the voltage to cancel the offset.

20. The power supplying apparatus of claim 19, wherein the comparator has an offset canceling period and a signal detecting period.

21. The power supplying apparatus of claim 20, wherein the offset canceling period and the signal detecting period are repeated.

22. The power supplying apparatus of claim 19, wherein the comparator comprises:
a first transconductance amplifier amplifying the voltage difference between the current level of the input power shifted by the level shifter and the ground; and
a second transconductance amplifier providing the compensation current according to the offset generated by amplification of the first transconductance amplifier.

23. The power supplying apparatus of claim 22, wherein the first transconductance amplifier outputs an output signal to the second transconductance amplifier, and
the output signal of the first transconductance amplifier and an output signal of the second transconductance amplifier are combined.

24. The power supplying apparatus of claim 22, wherein the comparator further comprises:
a first switch connected between an output terminal of the level shifter and an input terminal of the first transconductance amplifier;
a second switch connected between a terminal of the first switch and the ground;
a third switch connected between an output terminal of the first transconductance amplifier and an input terminal of the second transconductance amplifier; and
a capacitor connected between the input terminal of the second transconductance amplifier and the ground.

25. The power supplying apparatus of claim 23, wherein the comparator further comprises an inverting amplifier inverting-amplifying an output signal generated by using the output signal of the first transconductance amplifier and the output signal of the second transconductance amplifier.

26. The power supplying apparatus of claim 24, wherein the first and second switches are turned-on and the third switch is turned-off during an offset canceling period, and
the first and second switches are turned-off and the third switch is turned-on during a signal detecting period.
